(19) United States
(12) Patent Application Publication
(10) Pub. No.: US 2016/0013129 A1
(43) Pub. Date: Jan. 14, 2016

(54) SEMICONDUCTOR MEMORY DEVICE

(71) Applicant: KABUSHIKI KAISHA TOSHIBA, Tokyo (JP)

(72) Inventors: YUKI SOH, Yokkaichi Mie (JP); Masayoshi Tagami, Kuwana Mie (JP); Yoshiaki Himeno, Kuwana Mie (JP)

(21) Appl. No.: 14/635,999

(22) Filed: Mar. 2, 2015

Related U.S. Application Data
(60) Provisional application No. 62/024,178, filed on Jul. 14, 2014.

(51) Int. Cl. H01L 23/528; H01L 23/522; H01L 21/768; H01L 27/112

(52) U.S. Cl. CPC H01L 23/528; H01L 27/11293; H01L 23/5226; H01L 21/76802; H01L 21/76877

(57) ABSTRACT

A semiconductor memory device includes a substrate, a plurality of bit lines extending in a first direction parallel to a main surface of the substrate, a plurality of selection gates extending in a second direction perpendicular to the first direction, and a contact region between the selection gates on the substrate and includes a plurality of contacts respectively formed under the bit lines. The contact region is formed so that N (N≧3) contacts are disposed under the N adjacent bit lines on a straight line that is not parallel to the first and second directions. A first dummy contact is located under a first bit line of the N adjacent bit lines, and a second dummy contact located under the N-th bit line among the N adjacent bit lines.

### CROSS-REFERENCE TO RELATED APPLICATION

This application is based upon and claims the benefit of priority from U.S. Provisional Patent Application No. 62/024,178, filed Jul. 14, 2014, the entire contents of which are incorporated herein by reference.

### FIELD

Embodiments of the present invention relate to a semiconductor memory device.

### BACKGROUND

As an example of a semiconductor memory device, for example, a NAND type flash memory device, there is a demand for an increase in the density of memory cells on a single device and thus a requirement for greater integration, and thus reduction in the size of a memory cell array has progressed. As a result of this progression, the distance between bit lines disposed between selection gates on the drain side is reduced, and the arrangement of the contacts, or the sizes thereof, must be modified to continue the reduction in the spacing of the bit lines.

### BRIEF DESCRIPTION OF THE DRAWINGS

FIG. 1 is an example of an equivalent circuit diagram illustrating a part of a memory cell array formed in a memory cell region of a NAND type flash memory device according to an embodiment.

FIG. 2 is an example of a plan view illustrating a layout pattern of a part of the memory cell region.

FIG. 3 is an example of an enlarged plan view illustrating a bit line contact region and a region including selection gate lines adjacent thereto in FIG. 2.

FIG. 4 is an example of a view schematically illustrating a longitudinal cross-sectional view for illustrating the structure according to a first embodiment.

FIGS. 5A to 5C are examples of longitudinal cross-sectional views illustrating a method of manufacturing a semiconductor memory device according to the first embodiment.

FIGS. 6A to 6C are examples of longitudinal cross-sectional views illustrating the method of manufacturing a semiconductor memory device according to the first embodiment.

FIGS. 7A to 7C are examples of longitudinal cross-sectional views illustrating the method of manufacturing a semiconductor memory device according to the first embodiment.

FIGS. 8A to 8C are examples of longitudinal cross-sectional views illustrating the method of manufacturing a semiconductor memory device according to the first embodiment.

FIGS. 9A and 9B are examples of views illustrating planar layouts of a change in the pattern of the mask 20 for comparison before the etching and after the etching in a manufacturing process according to the first embodiment.

FIG. 10 is an example of a plan view illustrating a second embodiment.

FIG. 11 is an example of a longitudinal cross-sectional view illustrating the second embodiment and is an example of a longitudinal cross-sectional view of a part taken along the line 11-11 in FIG. 10.

FIG. 12 is an example of a plan view illustrating a third embodiment.

FIG. 13 is an example of a plan view illustrating a fourth embodiment.

FIG. 14 is an example of a plan view illustrating a fifth embodiment.

FIG. 15 is an example of a plan view illustrating a sixth embodiment.

### DETAILED DESCRIPTION

A semiconductor memory device according to this embodiment includes a substrate, a plurality of bit lines that are located on the substrate to extend in a first direction parallel to a main surface of the substrate, a plurality of selection gates located on the substrate to extend in a second direction perpendicular to the first direction, and a contact region located between the selection gates on the substrate, including a plurality of contacts respectively formed under the bit lines. The contact region is formed so that N (N is an integer that is equal to or greater than 3) contacts are disposed under N adjacent bit lines on a straight line that is not parallel to the first and second directions. A first dummy contact and a second dummy contact are located adjacent to, and outside of, the contact region, the first dummy contact located under a first bit line of the N adjacent bit lines, and the second dummy contact located under the N-th bit line among the N adjacent bit lines.

### First Embodiment

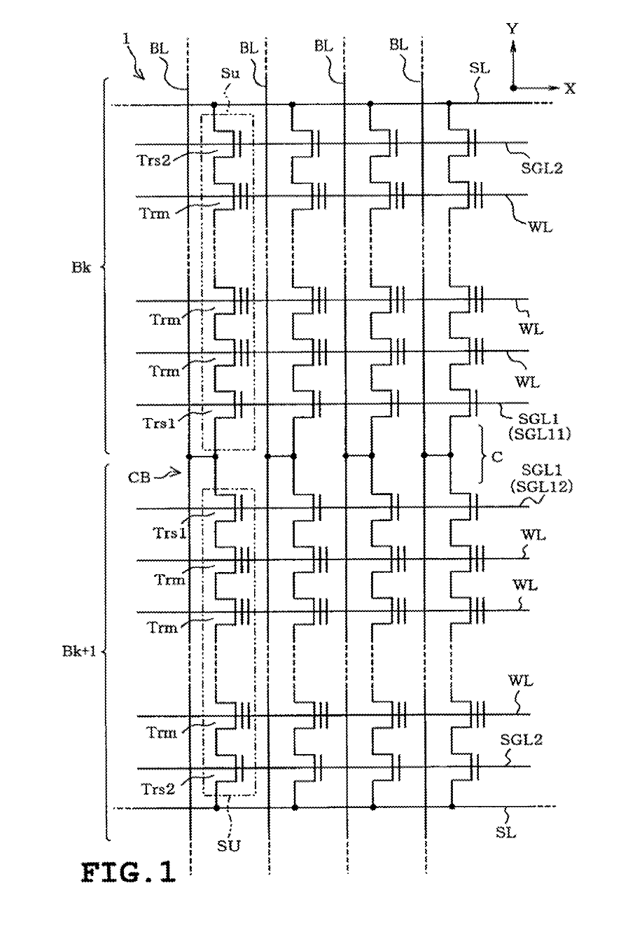

Hereinafter, a first embodiment of a semiconductor memory device configured as a NAND type flash memory device will be described with reference to FIGS. 1 to 9. In the following description, like elements having substantially the same functions and configurations are denoted by like reference numerals, and the repeated description thereof will be appropriately omitted. The drawings are schematic, and the relationship between thicknesses and planar dimensions, the ratio of the thicknesses of layers, and the like are not necessarily coincide with those of an actual device. In addition, terms that represent directions such as up and down in the description indicate relative directions in a case where the element formation surface side of a semiconductor substrate faces upward and may be different from directions which are based on the direction of gravitational acceleration.

In addition, in the following description, for convenience of description, an XYZ orthogonal coordinate system is used. In the coordinate system, two orthogonal directions which are parallel to the surface of the semiconductor substrate are referred to as an X direction and a Y direction, a direction in which word lines WL extend is referred to as the X direction, and a direction which is orthogonal thereto and in which bit lines BL extend is referred to as a Y direction. A direction orthogonal to both the X direction and the Y direction is referred to as a Z direction.

First, the configuration of a NAND type flash memory device 1 according to this embodiment will be described. FIG. 1 is an example of an equivalent circuit diagram illustrating a part of a memory cell array formed in a memory cell region of the NAND type flash memory device 1 according to the embodiment.

As illustrated in FIG. 1, the NAND type flash memory device 1 includes the memory cell array in which a number of memory cells are disposed in a matrix form, i.e., the memory cells extend in the X and the Y direction. The NAND type flash memory device 1 includes a plurality of NAND cell units SU, and each NAND cell unit SU includes two selection gate transistors Trs1 and Trs2. A plurality of (for example, 64) memory cell transistors Trm which are connected in series are disposed between the selection gate transistors Trs1 and Trs2. The memory cell transistors Trm interposed between the selection gate transistors Trs1 and Trs2 and the selection gate transistors Trs1 and Trs2 together are referred to as a NAND cell unit SU. In the NAND cell unit SU, the adjacent memory cell transistors among the plurality of memory cell transistors Trm share source/drain regions, i.e., the drain of one memory cell transistor TRM is the source of the adjacent memory cell transistor Trm, and vice versa. The NAND cell units SU are disposed in a matrix form. In addition, the NAND type flash memory device 1 includes a dummy memory cell (not illustrated) in the NAND cell unit SU as necessary.

In FIG. 1, the memory cell transistors Trm of adjacent cell units SU which are disposed in the X direction (word line direction) are connected to a word line WL electrically in common. In FIG. 1, the selection gate transistors Trs1 disposed in the X direction are connected to a selection gate line SGL1 electrically in common, and the selection gate transistors Trs2 are connected to a selection gate line SGL2 electrically in common.

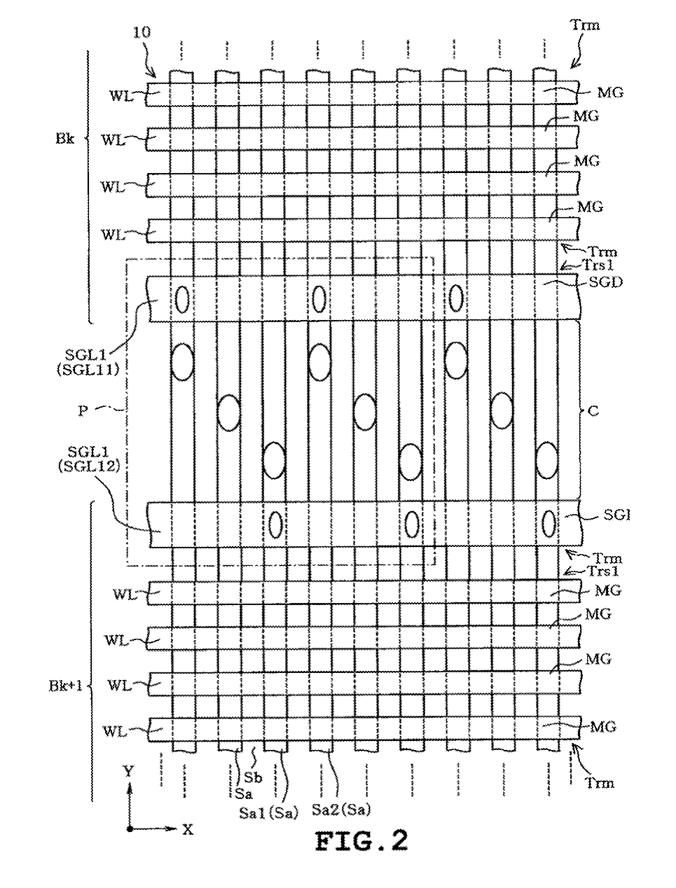

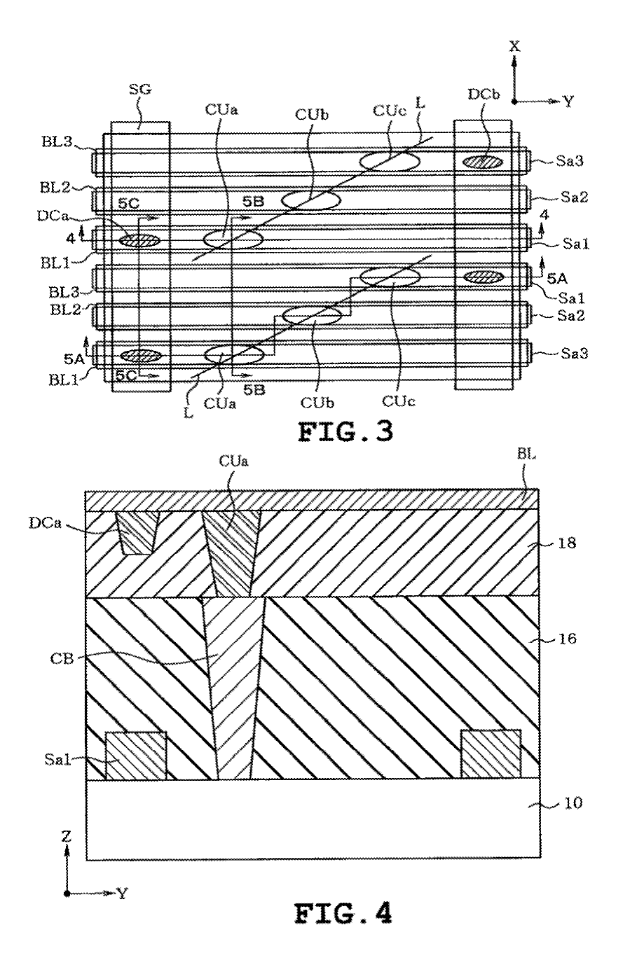

Bit line contacts CB (CBa, CBb, and CBc in FIGS. 2 and 3 which will be described later) are connected to the drain regions of the selection gate transistors Trs1. The bit line contacts CB extend in the Y direction (bit line direction) in FIG. 1, and are respectively connected to a plurality of bit lines BL that are disposed in parallel in the X direction. In addition, the selection gate transistors Trs2 are connected to a source line SL that extends in the X direction in FIG. 1 via the source regions.

FIG. 2 is an example of a plan view illustrating a layout pattern of apart of the memory cell region. FIG. 3 is an example of an enlarged plan view illustrating a region C in which the bit line contacts or upper contacts CU are formed (hereinafter, referred to as a region C) and a region P including the selection gate lines SGL1 (SGL11 and SGL12) adjacent to the region C. As illustrated in FIGS. 2 and 3, element isolation regions Sb having an ST1 (Shallow Trench Isolation) structure are formed into a semiconductor substrate 10 and extend thereon along the Y direction in the figures. A plurality of the element isolation regions Sb are formed at predetermined intervals spaced in the X direction in the figures between adjacent element isolation regions Sb. Element regions Sa are formed to extend along the Y direction in the figures each of the plurality of the element regions Sa is isolated from the adjacent element region Sa in the X direction by the element isolation regions Sb. That is, the plurality of the element regions Sa extend in the Y direction to be disposed in a line (mesa)-and-space pattern. The element regions Sa are spaced, for example, at the minimum pitch of a minimum design dimension in the X direction.

The word lines WL are formed to extend along a direction (the X direction in the figures) that orthogonally intersects the element regions Sa, and extend over, and spaced from, the element regions Sa. A plurality of the word lines WL are formed at predetermined intervals in the Y direction in the figures. Where an element region Sa extends below a word line WL, a memory cell gate electrode MG of the memory cell transistor Trm is formed.

As illustrated in FIG. 1, a plurality of memory cell transistors Trm which are connected in series and extend in the Y direction become a portion of a NAND string (memory cell string). The selection gate transistors Trs1 and Trs2 are located at opposed ends of the memory cell at the end portion of the NAND string in the Y direction.

A plurality of the selection gate transistors Trs1 are disposed in the X direction, and selection gate electrodes SGD (see FIG. 2) of the plurality of the selection gate transistors Trs1 are electrically connected to the selection gate line SGL1. In addition, selection gate electrodes SGD of the memory cell transistors Trs1 are formed on the element regions Sa where they pass below the selection gate line SGL1.

In addition, as illustrated in FIG. 1, a plurality of the selection gate transistors Trs2 are disposed in the X direction, and selection gate electrodes (not illustrated in FIG. 2) of the plurality of the selection gate transistors Trs2 are electrically connected to the selection gate line SGL2. In addition, selection gate electrodes (not illustrated) are also formed on the element regions Sa where they pass below the selection gate line SGL 2.

As illustrated in FIGS. 2 and 3, the region C is provided in the area between the selection gate transistors Trs1 and Trs1 of the NAND cell units SU. In the region C, a plurality of bit line contacts CB (CBa, CBb, and CBc) are formed. On the bit line contacts CB, the upper contacts CU (CUa, CUb, and CUc) are formed.

The plurality of the bit line contacts CBa, CBb, and CBc are respectively formed on the plurality of the element regions Sa. The bit line contacts CBa, CBb, and CBc and the upper contacts CUa, CUb, CUc are formed on the element regions Sa between the adjacent selection gate transistors Trs1 and Trs1 one by one. That is, the bit line contact CB (CBa, CBb, and CBc) and the upper contact CU (CUa, CUb, and CUc) are disposed to overlap in the same location. In addition, the bit line BL is disposed to extend over the element region Sa in the plan view of FIGS. 2 and 3. The bit line contacts CBa, CBb, and CBc and the upper contacts CUa, CUb, CUc are formed below the bit lines BL in the region between selection gate transistors Trs1 and Trs1 of adjacent cell units SU extending along generally the path line in the Y direction, i.e., between adjacent bit lines BL.

As illustrated in FIGS. 2 and 3, in the plan view (top view), the upper contact CUa formed above the first element region Sa1 in the X direction or under the bit line BL (BL1) is disposed so that the position thereof in the Y direction is close to the selection gate line SGL11 (the selection gate electrode SGD) of a block Bk. The upper contact CUc formed above the third element region Sa (Sa3) in the X direction or under the bit line BL (BL3) is disposed so that the position thereof in the Y direction is close to the selection gate line SGL12 (the selection gate electrode SGD) of a block Bk+1. The upper contact CUb formed above the second element region Sa (Sa2) in the X direction or under the bit line BL (BL2) is disposed so that the position thereof in the Y direction is at an intermediate position between the upper contacts CUa and CUc. The upper contacts CUa, CUb, and CUc are present on the semiconductor substrate 10, for example, in a direction in which the centers of the upper contacts are parallel to each other on a straight line L which is not parallel to the X direction and the Y direction. That is, the three contacts that are the continuous upper contacts CUa, CUb, and CUc are disposed above the continuous element regions Sa1, Sa2, and Sa3 or under the continuous bit lines BL1, BL2, and BL3 along the straight line L.

Dummy contacts DC (DCa and DCb) are respectively disposed at positions adjacent to the upper contacts CUa in a region over opposing selection gate lines SGL1 to the side of the region C. A dummy contact DCa is disposed in an area above the same element region Sa1 as that to which the upper contact CUa and the bit line contact CBa are connected, and under the bit line BL1 as that to which the upper contact CUa is connected. The dummy contact DCb is disposed above the same element region Sa3 as that to which the upper contact CUc and the bit line contact CBc are connected and under the bit line BL3 to which the upper contact CUc is connected. The dummy contact DC is present under the bit line BL which is positioned thereover. When the dummy contact DC is present in this region, the dummy contact DC is not short-circuited to the adjacent bit line BL. The upper contacts CUa, CUb, and CUc and the dummy contacts DCa and DCb which are disposed to be adjacent as described above are referred to as one unit, and the one unit is repeated in the X direction.

As such, in the first embodiment, in the plan view (top view), the upper contacts CUa, CUb, and CUc are disposed above the three continuously adjacent element regions Sa (Sa1, Sa2, and Sa3) in a staggered pattern in which the locations thereof in the Y direction are shifted (a so-called three series staggered disposition in which three series contacts are referred to as a repetition unit of a staggered structure). In the first embodiment, in the plan view (top view), the upper contacts CUa, CUb, and CUc are disposed under three adjacent bit lines BL (BL1, BL2, and BL3) in a staggered pattern in which the locations thereof in the Y direction are shifted (a so-called three series staggered disposition in which three series contacts are referred to as a repetition unit of a staggering structure). In addition, in the first embodiment, the three series staggered disposition in which the three upper contacts CU are repeatedly disposed is exemplified in the description, but the first embodiment is not limited thereto. In the first embodiment and embodiments that are described later, the number of the upper contacts CU is not limited to three, and an N series staggered disposition (N is an integer that is three or greater) in which arbitrary N upper contacts CU are repeatedly disposed (to be referred to as a four series staggering disposition or a five series staggering disposition).

As described above, in this configuration, the interval between the adjacent upper contacts CU is increased as compared to the distance between the adjacent bit lines or element areas Sa1, Sa2, etc., and thus the distance between the adjacent upper contacts CU may be further increased as compared to locating them in a line in the Y direction, .e., in a line generally perpendicular to the bit lines BL and elements areas Sa1, Sa2, etc. In addition, the dummy contacts DC (DCa and DCb) are disposed adjacent to the outer perimeter or edge the region C in which the upper contacts CUa, CUb, and CUc disposed in the three series staggered disposition. With this configuration, a reduction in non-opening of the bit line contact CBb which is at the intermediate position of the upper contacts CUa, CUb, and CUc disposed in the three series staggering disposition may be achieved.

As illustrated in FIGS. 2 and 3, the upper contact CU has an elliptical shape in cross section with a major axis in the Y direction and thus along the length direction of the bit lines BL and the element areas Sa1, Sa2, etc., and a minor axis in the X direction in the plan view in the width direction of the bit lines BL and the element areas Sa1, Sa2, etc. The dummy contact DC likewise has an elliptical shape with a major axis in the Y direction and a minor axis in the X direction in the plan view. The size (the major axis and the minor axis) of the dummy contact DC is formed to be smaller than the size of the upper contact CU. Accordingly, as described later, in the longitudinal cross-section of the dummy contact DC, the height of the bottom surface of the contact may be located above the height of the bottom surface of the upper contact CU. Accordingly, a short circuit extending through the dummy contact DC between the bit line BL and the selection gate electrode SG may be suppressed.

Hereinabove, the basic configuration of the NAND type flash memory device 1 to which this embodiment is applied has been described.

Next, the cross-sectional structure according to the first embodiment will be described with reference to FIG. 4. FIG. 4 is a cross-sectional view of FIG. 3 at section 4-4, illustrating the structure according to the first embodiment.

On the semiconductor substrate 10, as illustrated in FIG. 3, the element regions Sa and the element isolation regions Sb extend in the Y direction and are alternately disposed in the X direction to form a line-and-space pattern. In the element isolation region Sb, an element isolation insulating film is formed. In the longitudinal cross-sectional view of FIG. 4, the element region Sa1 that extends in the Y direction is illustrated. As the semiconductor substrate 10, for example, a silicon substrate may be used. As the element isolation insulating film, for example, a silicon oxide film may be used.

On the semiconductor substrate 10, a first insulating film 16 and a second insulating film 18 are formed. In addition, on the semiconductor substrate 10, the selection gate electrode SG is formed. The bit line contact CB, the upper contact CU, and the dummy contact DC are formed to penetrate through the first insulating film 16 and the second insulating film 18 from the upper surface to the lower surface thereof. On the second insulating film 18, the bit line BL is provided and it is connected to the upper contact CU. As the first insulating film 16 and the second insulating film 18, for example, silicon oxide films may be used.

The selection gate electrode SG is formed of a conductive film, and as the conductive film, for example, silicon (Si), tungsten (W), a layered film of tungsten and silicon (Si), or the like may be used. The bit line contact CB is formed of a conductive film, and for example, is formed of a layered film of a barrier metal including titanium (Ti) and titanium nitride (TiN) and tungsten. The barrier metal prevents the formation of silicide due to the reaction between the tungsten and the semiconductor substrate 10 (silicon). The lower portion of the bit line contact CB contacts the upper surface of the element region Sa1. The upper surface of the bit line contact CB comes into contact with the lower surface of the upper contact CU.

A conductive film is embedded (filled) into a via or contact extending through the second insulating film 18 the upper contact CU, and as the conductive film, for example, tungsten may be used. The bottom surface of the upper contact CU comes into contact with the upper surface of the bit line contact CB. The upper surface of the upper contact CU comes into contact with the lower surface of the bit line BL.

The dummy contact DC is positioned above the selection gate electrode SG. That is, as illustrated in FIG. 3, in a layout in the plan view, the two overlap each other. The position of the lowermost (bottom) surface of the dummy contact DC is located above the position of the upper surface of the selection gate electrode SG. Therefore, the dummy contact DC and the selection gate electrode SG do not come into contact with each other. In addition, the position of the bottom surface of the dummy contact DC is located above the position of the bottom surface of the upper contact CU. This is because the contact diameter of the dummy contact DC is smaller than the contact diameter of the upper contact CU.

A conductive film is embedded (filled) in an opening in the second insulating film 18 to form the dummy contact DC. The conductive film is the same material as that of the conductive film forming the upper contact CU described above. For example, tungsten may be used. The upper surface of the dummy contact DC comes into contact with the lower surface of the bit line BL.

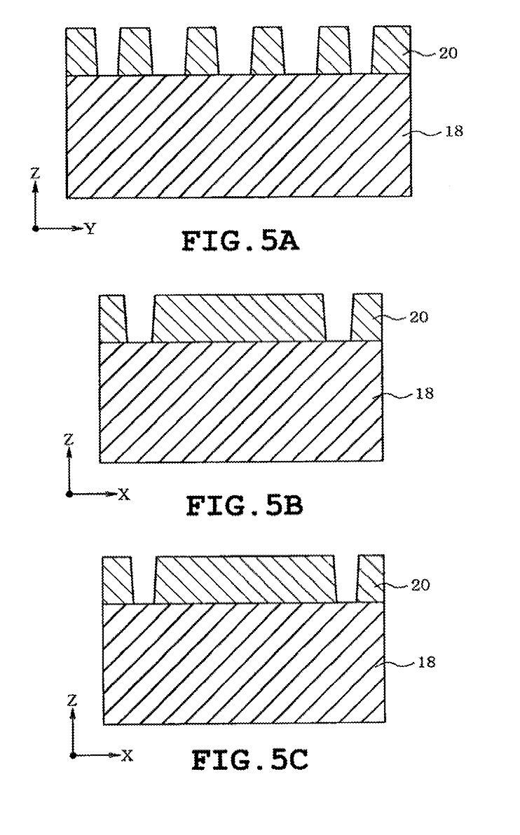

Next, a method of manufacturing a semiconductor memory device according to the first embodiment will be described with FIGS. 5A to 8C. FIGS. 5A, 6A, 7A, and 8A illustrate longitudinal cross-sectional views taken along the line 5A-5A of FIG. 3. FIGS. 5B, 6B, 7B, and 8B illustrate longitudinal cross-sectional views taken along the line 5B-5B of FIG. 3. FIGS. 5C, 6C, 7C, and 8C illustrate longitudinal cross-sectional views taken along the line 5C-5C of FIG. 3. FIGS. 5A to 8C illustrate states in the corresponding steps of the manufacturing process according to the first embodiment. In addition, FIGS. 5A to 8C illustrate parts positioned on the first insulating film 16 in FIG. 4.

First, as illustrated in FIGS. 5A to 5C, a patterned mask 20 is formed on the second insulating film 18 formed on the semiconductor substrate 10. The mask 20 may be, for example, a resist film or a hard mask such as a carbon film. Otherwise, for example, a layered film of a resist film, an SOG (Spin On Glass) film, and a carbon film may also be used. The mask 20 is patterned into the patterns of the upper contacts CU and the dummy contacts DC and is open at the position of each contact so that the surface of the second insulating film 18 is exposed. The dimension of the opening of the dummy contact DC is formed to be smaller than the dimension of the opening of the upper contact CU.

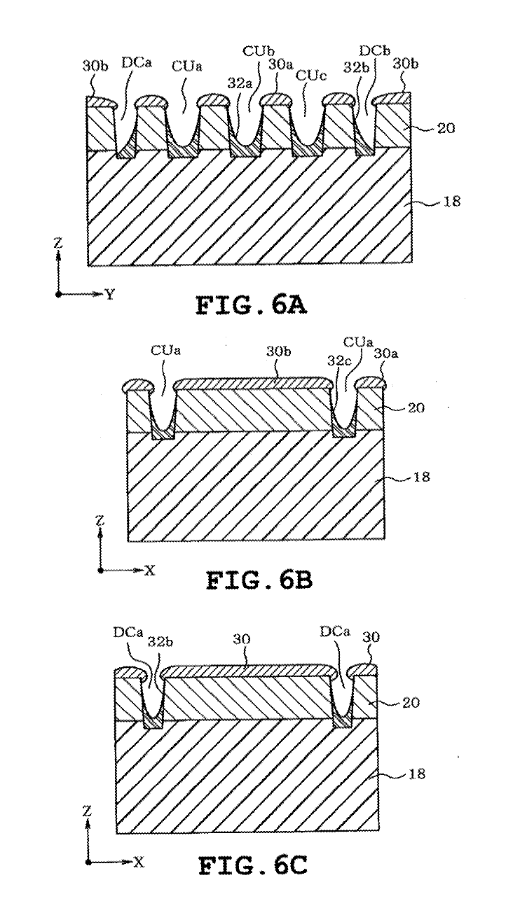

Next, the semiconductor substrate 10 is first placed in an etching chamber, and a recess is etched inwardly of the portions of the insulating layer 18 exposed at the base of the openings in the mask. During the etching step, by adjusting the composition of the etching gas chemistry to increase the presence of deposition gas in the etching gas, such as by increasing the concentration of CF4, non-conformal deposits 30a, 30b, 32a, and 32b are formed as shown in FIGS. 6A to 6C. The deposits 30a and 30b are formed on the upper surface of the mask 20. The deposit 32a is formed in the upper contact CU. The deposit 32b is formed in the dummy contact DC. The deposits 32a and 32b have poor coatability and thus are not formed conformally on the surface of the mask 20. Hereinafter, the deposits 30a, 30b, 32a, and 32b are collectively called a deposit 30. The deposit 30 is formed on the mask 20, and the portions thereof formed on the upper surfaces of the mask 20 overhang the opening in the mask 20 in the Y direction. The deposit 32a is formed in the upper contact CU and is formed thick at the bottom portion and thin along the side wall portion. The deposit 30b formed at the upper end of the mask 20 for forming the pattern of the dummy contact DC is formed in an overhang shape or an overhang shape that protrudes from the upper surface of the mask 20 a slightly greater distance in the Y direction than the overhang of deposit 30a in the transverse direction. The deposit 30b positioned on the resist layer at the side of a dummy contact DC opposed to the adjacent upper contacts UC has a greater overhang shape than that of the deposits 30a formed at points at which the upper contacts CU are disposed to be adjacent to each other. That is, at the upper corner of the openings which form the dummy contacts, the deposit (the deposit 30d) is formed to protrude further over the opening than it does at the other openings.

In addition, the deposit 30 is also deposited in the dummy contact DC. In the contact (the dummy contact DCa) on the outermost side furthest from the openings for the upper contacts UC, the deposit 32b is small at a position below the overhang of the deposit 30b due to the deposit 30b shadowing the sidewall of the opening. The deposit 32b is formed to have a large thickness on a side opposite to a side where the deposit 30b is formed and thus has an asymmetrical shape in the Y direction in FIG. 6A.

As described above, when deposition conditions are achieved during etching, a deposit having a large overhang shape is formed at the upper end portion of the contact that is positioned on the outermost side of a group of contacts, i.e., a contact that has another contact on only one side thereof. When the overhang protruding over the opening is formed at the upper portion of the contact, the sidewall and base of the contact opening is shadowed by the overhang, and less deposition material can reach that location, and the resulting deposited film layer is thin (small in amount). On the surface of the resist layer 20 adjacent the upper contact openings, the deposit has a smaller overhang, and thus the deposit reaching the sidewalls and base of the opening have a larger thickness, and the sidewalls are covered on the sides wall of the openings). Therefore, there may be a problem of insufficient removal by etching of a contact at the center portion of a group of contacts after the etching, a reduction in the contact diameter formed after the etching, or non-opening of the contact (contact opening failure).

In this embodiment, the dummy contacts DC are provided to either side of the region C where the upper contacts CU are formed. Accordingly, during the etching under the deposition conditions, the formation of a deposit having a large overhang shape at the upper end portion of the upper contact CU may be suppressed. Therefore, in any of the upper contacts CUa, CUb, and CUc, deposits 32a having the same thickness and thickness profile are formed, and non-uniformity occurs in the dummy contact which does not form a circuit element of the fabricated device. Accordingly, non-uniformity of the etching of the upper contacts CUa, CUb, and CUc does not occur, and thus a reduction in the contact diameter of the upper contact Cub positioned at the center portion or the occurrence of opening failure of the contact may be suppressed.

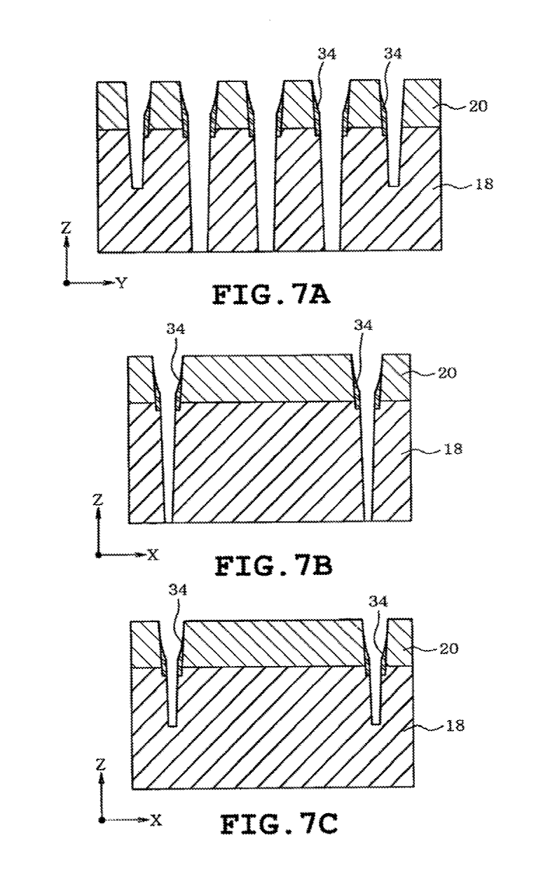

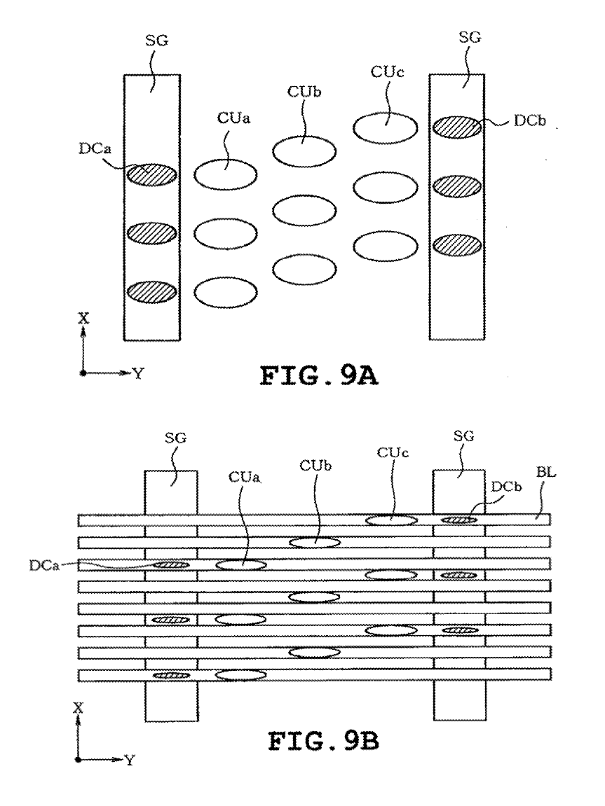

Next, as illustrated in FIGS. 7A to 7C, etching of the second insulating film 18 is formed by using the openings in the mask 20, as modified by the deposits 30, as the etch mask. The etching may be performed by using, for example, an RIE (Reactive Ion Etching) method under anisotropic (directional etching) conditions. In addition, the etching is performed under a condition in which deposits are deposited on the substrate during etching, such as by adding a deposition gas at the beginning of the etching step and after de-scumming has been performed. At this time, etching has progressed while the deposits 30 (30a, 30b, 32a, and 32b) are removed in the longitudinal direction during the etching and new deposits are deposited under the deposition conditions. As a result, side walls 34 formed by the deposits are deposited on the side surface of the openings of the mask 20. Accordingly, the pattern of the mask 20 is transferred onto the second insulating film 18 while the contact diameter of the upper contact CU and the contact diameter of the dummy contact DC are reduced. That is, the pattern dimensions (the contact diameter) of the mask 20 are reduced (shrink) to be transferred onto the second insulating film 18. FIGS. 9A and 9B illustrate this form. FIGS. 9A and 9B are examples of views illustrating planar layouts of a change in the pattern of the mask 20 (the patterns of the upper contact CU and the dummy contacts DC) for comparison before the etching and after the etching in the manufacturing process according to the first embodiment. FIG. 9A illustrates a contact pattern formed on the mask 20. FIG. 9B illustrates a contact pattern transferred onto the second insulating film 18. As illustrated in FIGS. 9A and 9B, the pattern dimensions (the contact diameters of the upper contacts CUa, CUb, and CUc and the dummy contacts DCa and DCb) of the mask 20 are reduced (shrunk) to be transferred onto the second insulating film 18.

The contact diameter of the dummy contact DC is formed smaller than that of the upper contact CU in the mask 20. As a result, the contact is less likely to fully open in the depth direction of the layer 18 by etching compared to the upper contact CU, and as illustrated in FIG. 7C, terminates partway into the thickness direction (Z direction) of the second insulating film 18. As described above, the dummy contact DC does not penetrate through the second insulating film 18 and does not reach the lower surface of the second insulating film 18. That is, the contact hole of the dummy contact DC is not open to the lower surface of the first conductive film 28. The upper contact CU (CUa, CUb, and CUc) has a greater contact diameter than that of the dummy contact DC and thus penetrates through the second insulating film 18 and reaches the lower surface of the second insulating film 18 during the etching. That is, the contact hole is open. By providing the dummy contact at both ends of a string or array, the resultant excessive overhang that would otherwise occur at the dummy contacts at the ends of the string or array occurs during the aforementioned etching (and deposition) in the dummy contact. Thus, the actual contacts (upper contact CU) are not reduced in diameter, and these upper contacts CU extend fully through the second insulating film 18.

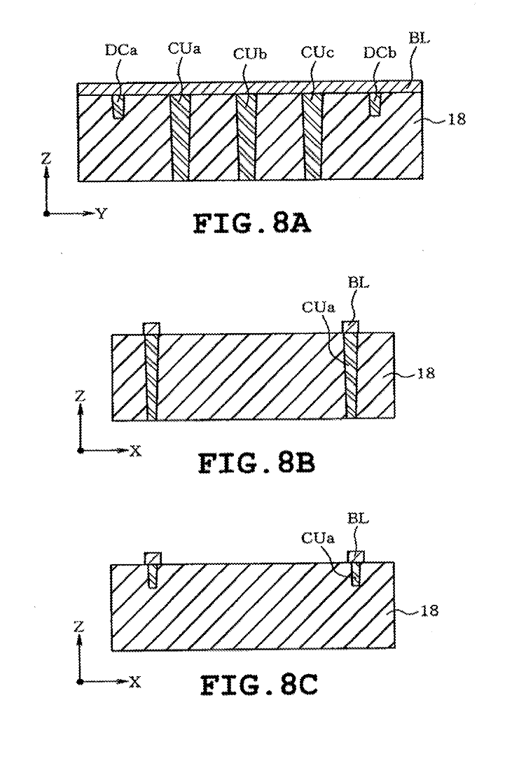

Next, as illustrated in FIGS. 8A to 8C, the mask 20 and the deposits 30 on the opening sidewalls are removed, plugs are formed by depositing conductive films in the upper contacts CU and the dummy contacts DC, and thereafter the bit lines BL are formed on the upper portion thereof. As the conductive film, for example, metal may be used. For example, tungsten (W) may be used. The upper portion of the plug comes into contact with the lower portion of the bit line BL. The bit line BL is formed of, for example, a metal film. For example, copper (Cu) may be used as the bit line BL material.

### Second Embodiment

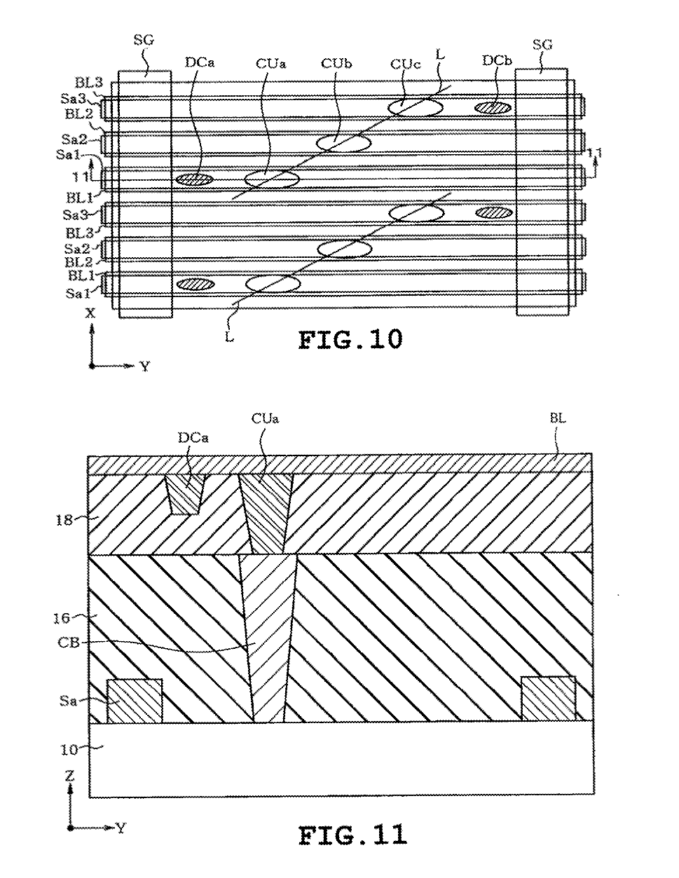

Next, a second embodiment will be described using FIGS. 10 and 11. FIG. 10 is an example of an enlarged plan view illustrating the region C and the region P including the selection gate lines SGL1 (SGL11 and SGL12) adjacent to the region C in FIG. 2. FIG. 11 illustrates an example of a longitudinal cross-sectional view of a part taken along the line 11-11 in FIG. 10. A difference from the first embodiment as shown in FIG. 4 is that the selection gate electrode SG is not present immediately below the dummy contact DC but the selection gate electrode SG is disposed to the exterior of the plurality of upper contacts CU and the dummy contact DC.

In this configuration, even when the dummy contact DC is deeply formed by the etching, the dummy contact DC does not come into contact with the selection gate electrode SG (at first element region Sa1) and extend will extend between the Contact CB and the location of the first element region Sa1. Therefore, a short circuit between the dummy contact DC and the selection gate electrode SG may be suppressed.

### Third Embodiment

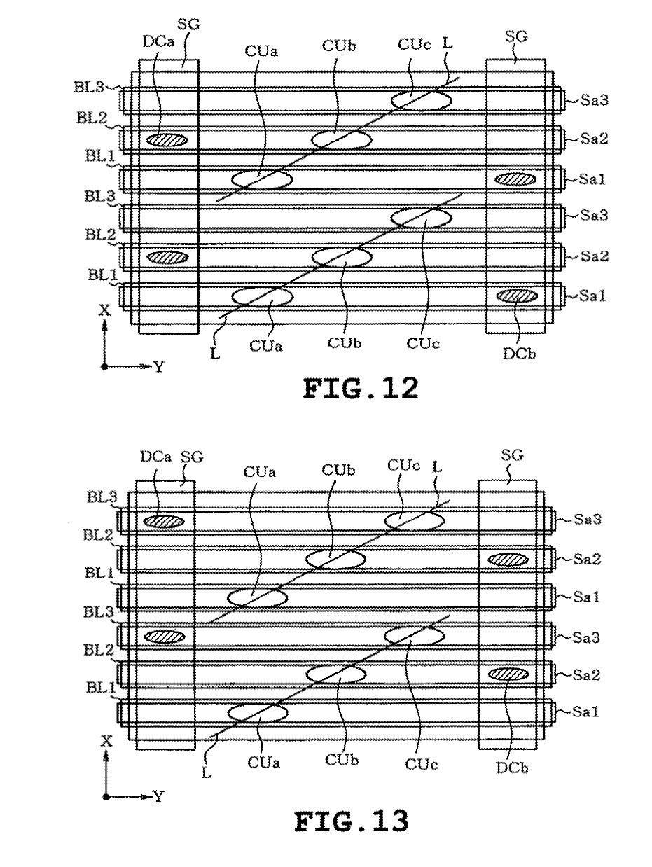

Next, a third embodiment will be described using FIG. 12. FIG. 12 is an example of an enlarged plan view illustrating the region C and the region P including the selection gate lines SGL1 (SGL11 and SGL12) adjacent to the region C in FIG. 2. A difference from the first embodiment is the position of the dummy contact DC.

In the first embodiment, the position of the dummy contact DCa in the X direction is laid on the first element region Sa1 (under the bit line BL1) and is formed adjacent to the upper contact CUa (see FIG. 3). In the third embodiment, the position of the dummy contact DCa in the X direction is laid on the second element region Sa2 (under the bit line BL2), and the position thereof in the Y direction is exterior to the region of the contact array of the region C like the position of the dummy contact DCa in FIG. 3.

In addition, in the first embodiment, the position of the dummy contact DCb in the X direction is laid on the third element region Sa3 (under the bit line BL3) and is formed adjacent to the upper contact CUc (see FIG. 3). In the third embodiment, the position of the dummy contact DCb in the X direction is laid on the first element region Sa1 (under the bit line BL1), and the position thereof in the Y direction is on the outside of the region C like the position of the dummy contact DCb in FIG. 3. With this configuration, the same effect as that of the first embodiment may be exhibited.

### Fourth Embodiment

Next, a fourth embodiment will be described using FIG. 13. FIG. 13 is an example of an enlarged plan view illustrating the region C and the region P including the selection gate lines SGL1 (SGL11 and SGL12) adjacent to the region C in FIG. 2. A difference from the first embodiment is the position of the dummy contact DC.

In the first embodiment, the position of the dummy contact DCa in the X direction is laid on the first element region Sa1 (under the bit line BL1) and is formed adjacent to the upper contact CUa (see FIG. 3). In the fourth embodiment, the position of the dummy contact DCa in the X direction is laid on the third element region Sa3 (under the bit line BL3), and the position thereof in the Y direction is on the outside of the region C like the position of the dummy contact DCa in FIG. 3.

In addition, in the first embodiment, the position of the dummy contact DCb in the X direction is laid on the third element region Sa3 (under the bit line BL3) and is formed adjacent to the upper contact CUc (see FIG. 3). In the fourth embodiment, the position of the dummy contact DCb in the X direction is laid on the second element region Sa2 (under the bit line BL2), and the position thereof in the Y direction is on the outside of the region C like the position of the dummy contact DCb in FIG. 3. With this configuration, the same effect as that of the first embodiment may be exhibited.

### Fifth Embodiment

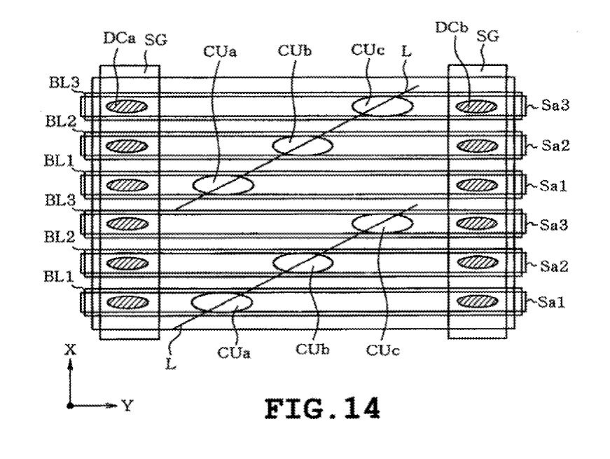

Next, a fifth embodiment will be described using FIG. 14. FIG. 14 is an example of an enlarged plan view illustrating the region C and the region P including the selection gate lines SGL1 (SGL11 and SGL12) adjacent to the region C in FIG. 2. A difference from the first embodiment is the position of the dummy contact DC.

In the first embodiment, as illustrated in FIG. 3, the position of the dummy contact DCa in the X direction is laid on the first element region Sa1 (under the bit line BL1) and is formed adjacent to the upper contact CUa. In the Y direction, the dummy contacts DCa are disposed in every two element regions Sa (every two bit lines BL). In the fifth embodiment, the positions of the dummy contacts DCa in the X direction are on the first, second, and third element regions Sa1, Sa2, and Sa3 (under the bit lines BL1, BL2, and BL3) and the positions thereof in the Y direction are positioned on the outside of the region C like the positions of the dummy contacts DCa in FIG. 3.

In the first embodiment, as illustrated in FIG. 3, the position of the dummy contact DCb in the X direction is laid on the third element region Sa3 (under the bit line BL3) and is formed adjacent to the upper contact CUc. In the Y direction, the dummy contacts DCb are disposed in every two element regions Sa (every two bit lines BL). In the fifth embodiment, the positions of the dummy contacts DCb in the X direction are on the first, second, and third element regions Sa1, Sa2, and Sa3 (under the bit lines BL1, BL2, and BL3) and the positions thereof in the Y direction are positioned on the outside of the region C like the positions of the dummy contacts DCa in FIG. 3.

Accordingly, the dummy contacts DC are disposed on all the element regions Sa (under the bit lines BL), and all the upper contacts CU (CU1, CU2, and CU3) are disposed to be interposed between the dummy contacts DC (DC1 and DC2) in the X direction. That is, the dummy contacts DC are disposed on the outside of all the upper contacts CU. Therefore, a reduction in the formed contact diameter of the upper contact Cub positioned at the center and non-opening of the contact (contact opening failure) may be further significantly suppressed.

### Sixth Embodiment

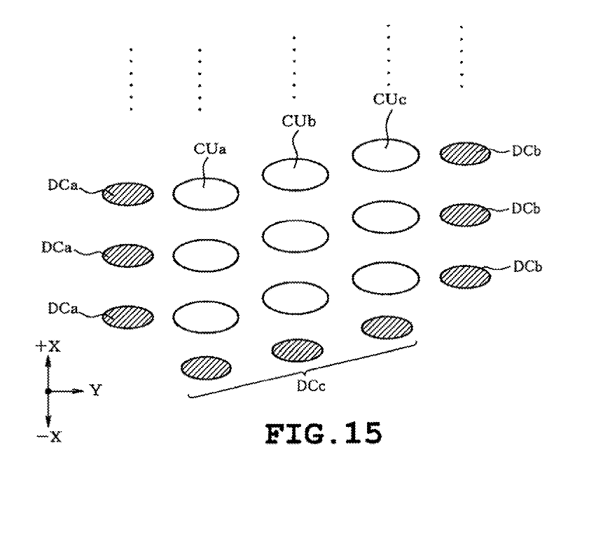

Next, a sixth embodiment will be described using FIG. 15. FIG. 15 is an example of a view illustrating a planar layout of the upper contacts CU and the dummy contacts DC. FIG. 13 is an example of a layout illustrating a layout in the end portion (array end) of the memory cell array.

In FIG. 15, one direction of the X direction is referred to as a +X direction, and the opposite direction thereof is referred to as a −X direction. In FIG. 15, the end portion in the −X direction becomes the array end. As illustrated in FIG. 15, as in the first embodiment, the dummy contacts DC (DCa and DCb) are disposed adjacent to the upper contacts CUa and CUc in the Y direction. In this embodiment, dummy contacts DCc are further disposed adjacent to the end portions in the −X direction of the upper contacts CUa, CUb, and CUc that are disposed in the X direction. The dummy contacts DC (DCa, DCb, and DCc) are disposed at positions adjacent to the plurality of the disposed upper contacts CUa, CUb, and CUc in the Y direction and positions adjacent to the end portions thereof in the X direction. That is, the dummy contacts DC (DCa, DCb, and DCc) are disposed in the periphery of the plurality of the disposed upper contacts CUa, CUb, and CUc in the X direction and the Y direction. In addition, although not illustrated, the dummy contacts DCc are also disposed even in the end portions in the +X direction,

The thickness of the deposit formed in the contact in the outermost periphery of points where a plurality of the contacts are disposed is reduced (decreased). Therefore, when etching is performed in this state, etching is excessively performed on the contact positioned in the outermost periphery and thus there may be cases where the depth of the contact is deeper or the contact diameter is increased. That is, there may be a case where the contact is excessively etched. In this embodiment, the dummy contacts DCc are further disposed on the outside of the outermost periphery of the upper contacts CU in the X direction. Therefore, since the periphery of the upper contacts CU is surrounded by the dummy contacts DC (DCa, DCb, and DCc), the upper contacts CU are not positioned in the outermost periphery. Therefore, excessive etching of the contact in the upper contact CU may be suppressed.

As described above, according to the sixth embodiment, the same effect as that according to the first embodiment is provided. Moreover, according to the sixth embodiment, excessive etching of the contact due to the thinning of the deposit in the upper contact CU in the end portion of the upper contacts CU in the Y direction may be suppressed.

### OTHER EMBODIMENTS

In the above-described embodiments, the bit line contacts CB and the upper contacts CU have elliptical shapes in the plan view. However, the shapes are not limited thereto and may be, for example, substantially true circle shapes.

In the above-described embodiments, an example applied to the NAND type flash memory device is described. However, non-volatile semiconductor memory devices such as a NOR type flash memory or an EPROM, semiconductor memory devices such as a DRAM or an SRAM, logic semiconductor devices such as a microcomputer may also be applied.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a plurality of bit lines located on the substrate to extend in a first direction parallel to a main surface of the substrate;
a plurality of selection gates located on the substrate to extend in a second direction perpendicular to the first direction;
a contact region located between the selection gates on the substrate, including a plurality of contacts respectively formed under the bit lines, the contact region being formed so that N, where N is an integer that is equal to or greater than three, contacts are disposed under N adjacent bit lines on a straight line that is not parallel to the first and second directions; and
a first dummy contact and a second dummy contact located adjacent to, and outside of, the contact region, the first dummy contact located under a first bit line of the N adjacent bit lines, and the second dummy contact located under the N-th bit line among the N adjacent bit lines.

2. The device according to claim 1,
wherein the first dummy contact and the second dummy contact are located at least partially over selection gates.

3. The device according to claim 2,
wherein bottom surfaces of the first dummy contact and the second dummy contact are spaced from the upper surfaces of the selection gates.

4. The device according to claim 1,
wherein the first dummy contact and the second dummy contact are located between the contact region and the selection gates.

5. The device according to claim 1,
wherein contact width of the first dummy contact and the second dummy contact are smaller than the contact widths of the contacts.

6. The device according to claim 1, further comprising:
a memory cell array including a plurality of memory cells on the substrate,
wherein N dummy contacts are further disposed at positions adjacent to the N contacts along the straight lines in the first direction, which are disposed at an end of the memory cell array.

7. The device according to claim 1,
wherein the first dummy contact is formed on the outside of the contact region and under a bit line to which the first contact among the N contacts is connected, and
the second dummy contact is formed under the bit line to which the N-th contact is connected.

8. The device according to claim 1,
wherein the first dummy contact is positioned on the outside of the contact region and under a bit line to which the second contact among the N contacts is connected, and
the second dummy contact is positioned under the bit line to which the first contact is connected.

9. The device according to claim 1,
wherein the first dummy contact is positioned on the outside of the contact region and under a bit line to which the N-th contact among the N contacts is connected, and
the second dummy contact is positioned under the bit line to which the second contact is connected.

10. The device according to claim 1,
wherein the first dummy contact and the second dummy contact are positioned on the outside of the contact region and under all bit lines to which the N contacts are connected.

11. The device according to claim 1,
wherein the N contacts, the first dummy contact, and the second dummy contact are referred to as one unit, and
the one unit is repeatedly disposed in the first direction.

12. The device according to claim 1, further comprising:
a plurality of lower contacts,
wherein the N contacts come into contact with the upper portions of the lower contacts.

13. The device according to claim 1,
wherein lower surfaces of the first dummy contact and the second dummy contact are positioned above lower surfaces of the contacts.

14. A semiconductor device, comprising:
a plurality of spaced apart element regions extending in a first direction in a semiconductor substrate;
a plurality of conductor lines extending over the element regions in the first direction;
a plurality of electrodes disposed on the substrate and arranged in a second direction crossing the first direction;
an insulation layer disposed between the conductor lines and the substrate and covering the overlying regions;
a plurality of contact openings extending through the insulation layer and exposing the electrodes at the base thereof, the plurality of contact openings arrayed along a line crossing the first and second directions and extending from the underside of the conductor lines; and
at least one dummy contact opening extending inwardly of the insulation layer below a conductor line, and terminating inwardly of the insulation layer.

15. The semiconductor device of claim 14, wherein the width of the dummy contact opening is smaller than the width of a contact opening.

16. The semiconductor device of claim 15, where the contact openings and dummy contact openings are filled with a metal.

17. The semiconductor device of claim 14, wherein the dummy contact opening terminates over, and spaced from, an element region.

18. A method of forming a semiconductor device, comprising:
providing a plurality of selection gate electrodes spaced apart from one another in a first direction;
forming an insulating layer over the selection gate electrodes;
forming a plurality of first openings, having a first minor diameter, partially inwardly of the insulating layer to a first depth;
forming a plurality of second openings, having a second minor diameter smaller than the first minor diameter, partially inwardly of the insulating layer to a first depth;
etching the first and second openings under conditions wherein etched material is redeposited in the openings further inwardly of the insulating layer to reduce the widths of the first and second openings;
further etching the first and second openings, such that the first openings extend through the insulating layer while the second openings terminating within the insulating layer;
filling the first and second openings with a metal; and
forming a plurality of spaced conductive lines over the insulating layer extending in a second direction crossing the first direction such that a conductive lines extend over the first openings and at least two of the plurality of conductive lines also extend over a second opening.

19. The method of claim 18, wherein at least one of the conductive lines does not extend over a second opening.

20. The method of claim 19, wherein the a plurality of first openings are spaced along a line crossing both the first and the second directions.
